(19) United States
(12) Patent Application Publication
(10) Pub. No.: US 2015/0303129 A1
(43) Pub. Date: Oct. 22, 2015

(54) THERMAL INTERFACE COMPOSITIONS AND METHODS FOR MAKING AND USING SAME

(71) Applicant: 3M INNOVATIVE PROPERTIES COMPANY, Saint Paul, MN (US)

(72) Inventors: Andrew J. Ouderkirk, St. Paul, MN (US); Ravi K. Sura, Woodbury, MN (US); Hun Jeong, Yongin-Si (KR)

(21) Appl. No.: 14/440,886

(22) PCT Filed: Nov. 6, 2013
(86) PCT No.: PCT/US2013/068620

§ 371 Date: May 6, 2015

Related U.S. Application Data
(60) Provisional application No. 61/724,327, filed on Nov. 9, 2012.

(51) Int. Cl. H01L 23/373; B29C 39/02; B29C 65/00; B29C 39/00

(52) U.S. Cl. CPC H01L 23/3737; B29C 39/003; B29C 39/026; B29C 66/45; B29C 66/74; B29C 66/73114; B29L 2031/34

(57) ABSTRACT

A thermal interface material includes a conformable component and a thermally conductive filler dispersed in the conformable component. The material is provided in at least two segments laterally spaced from one another to define one or more gaps, each of the segments having a length, a width, and a height. The average aspect ratio of length to height and/or width to height of the at least two segments is between 1:10 and 10:1.

### CROSS REFERENCE TO RELATED APPLICATIONS

This application claims the benefit of U.S. Provisional Application No. 61/724,327, filed Nov. 9, 2012, the disclosure of which is incorporated by reference herein in its entirety.

### FIELD

The present disclosure is directed to thermal management materials. More particularly, the present disclosure is directed to thermal management materials that may be used at an interface between electronic components in an electronic device.

### BACKGROUND

Various thermal interface materials have been provided with shallow surface features to accommodate air removal at the thermal interface during attachment to a surface. Various thermal interface materials having such surface features are described, for example, in U.S. Pat. No. 5,213,868 (Liberty et al.).

### SUMMARY

In some embodiments, a thermal interface material is provided. The thermal interface material includes a conformable component and a thermally conductive filler dispersed in the conformable component. The material is provided in at least two segments laterally spaced from one another to define one or more gaps, each of the segments having a length, a width, and a height. The average aspect ratio of length to height and/or width to height of the at least two segments is between 1:10 and 10:1.

In some embodiments, a method for making a thermal interface material is provided. The method includes providing a thermal interface material. The thermal interface material includes a conformable component and thermally conductive particles. The method further includes casting the thermal interface material into a mold. The mold is configured to provide the thermal interface material with a pattern whereby the thermal interface material is provided in at least two segments laterally spaced from one another to define one or more gaps, each of the segments having a length, a width, and a height. The average aspect ratio of length to height and/or width to height of the at least two segments is between 1:10 and 10:1. The method further includes removing the thermal interface material from the mold.

In some embodiments, a method for making an electronic device is provided. The method includes providing an article. The article includes a first release liner that includes a first release surface and a second release liner that includes a second release surface. A thermal interface material is disposed between the first and second release surfaces. The method further includes removing the first release liner to at least partially expose thermal interface material. The method further includes applying the thermal interface material to a substrate that includes an electronic or a thermal dissipative member.

The above summary of the present disclosure is not intended to describe each embodiment of the present disclosure. The details of one or more embodiments of the disclosure are also set forth in the description below. Other features, objects, and advantages of the disclosure will be apparent from the description and from the claims.

### BRIEF DESCRIPTION OF THE DRAWINGS

The disclosure may be more completely understood in consideration of the following detailed description of various embodiments of the disclosure in connection with the accompanying figures, in which:

FIGS. 1A-1B illustrate schematic top and side views, respectively, of a segmented TIM in accordance with some embodiments of the present disclosure.

FIGS. 2A-2B illustrate schematic top and side views, respectively, of a segmented TIM in accordance with some embodiments of the present disclosure.

FIGS. 3a-3b illustrate schematic perspective side views of a uniform sheet of a TIM and a segmented TIM, before and after compression, respectively, between components via a compressive force.

### DETAILED DESCRIPTION

As electronic devices become more powerful and are supplied in ever smaller packages, the electronic components in these devices have become smaller and more densely packed on integrated circuit boards and chips. To ensure that the electronic device operates reliably, the heat generated by these components should be efficiently dissipated. For example, to enhance conductive cooling, electronic components may utilize a thermal management material as a heat transfer interface between mating surfaces of a heat generating electronic component, such as an integrated circuit chip, and a thermal dissipation member such as, for example, a heat sink or a finned heat spreader. These thermal management materials positioned at heat transfer interfaces, referred to herein as thermal interface materials (TIMs), are designed to substantially eliminate insulating air between the electronic component and the thermal dissipation member, which enhances heat transfer efficiency.

The design of TIMs involves an inherent contradiction. On the one hand, the TIM must be conformable to accommodate variations in the gap between the heat source and the heat sink (due to, for example, uneven surfaces on the heat source and/or heat sink).

Conformability is typically provided to the TIM by a polymeric or oligomeric fluid or elastomer. The fluid may be polymerizable, or may undergo a melt transition at a temperature above the intended use temperature of the TIM. On the other hand, the material must effectively conduct heat. Materials that tend to enhance conformability, however, generally possess low thermal conductivity (e.g., about 0.2 W/mK). Consequently, fillers are commonly added to increase thermal conductivity. These fillers, however, increase the viscosity of the TIM, in the case of a thermal grease, or the modulus of the TIM, in the case of a thermal pad, thereby reducing the conformability. Therefore, TIMs having an optimized balance between conformability and thermal conductivity may be desirable.

### Definitions

As used herein, the singular forms “a”, “an”, and “the” include plural referents unless the content clearly dictates otherwise. As used in this specification and the appended embodiments, the term “or” is generally employed in its sense including “and/or” unless the content clearly dictates otherwise.

### Definitions

As used herein, the recitation of numerical ranges by endpoints includes all numbers subsumed within that range (e.g. 1 to 5 includes 1, 1.5, 2, 2.75, 3, 3.8, 4, and 5).

Unless otherwise indicated, all numbers expressing quantities or ingredients, measurement of properties and so forth used in the specification and embodiments are to be understood as being modified in all instances by the term “about.” Accordingly, unless indicated to the contrary, the numerical parameters set forth in the foregoing specification and attached listing of embodiments can vary depending upon the desired properties sought to be obtained by those skilled in the art utilizing the teachings of the present disclosure. At the very least, and not as an attempt to limit the application of the doctrine of equivalents to the scope of the claimed embodiments, each numerical parameter should at least be construed in light of the number of reported significant digits and by applying ordinary rounding techniques.

In some embodiments, the present disclosure relates to a thermal interface material provided in two or more segments. Generally, as will be discussed in further detail below, the segmented thermal interface materials of the present disclosure may accommodate conformability of the TIMs to the mating surfaces of components to be joined or connected by the TIM, while also promoting effective heat transfer between the components.

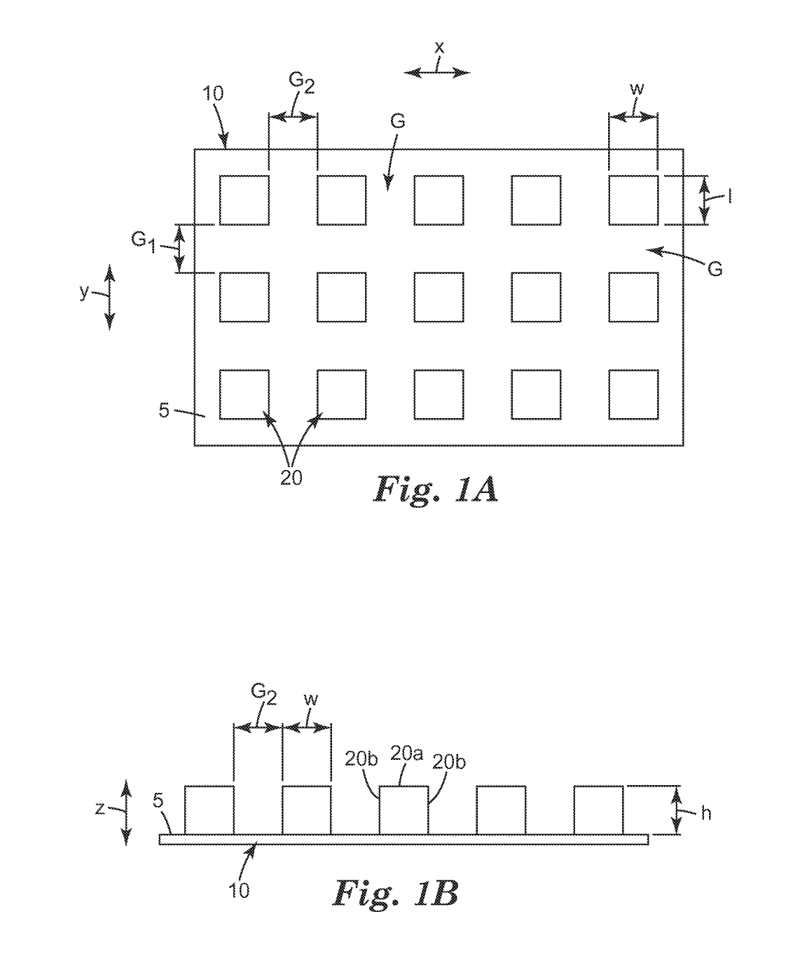

In various embodiments, the present disclosure further relates to a substrate bearing on one or more surfaces thereof (e.g., major surfaces), the segmented thermal interface materials of the present disclosure. For example, as shown in FIGS. 1A-1B, a major surface 5 of a substrate 10 may have disposed thereon an array of discrete TIM segments 20 laterally spaced such that the TIM segments 20 define one or more gaps or channels extending between the TIM segments 20. As will be discussed in further detail below, as compared to a conventional uniform sheet of a TIM, the gaps provided by the segmented TIMs of the present disclosure may provide improved compressibility and conformability upon compression of the TIM between components.

In illustrative embodiments, the TIMs of the present disclosure may include a conformable component and a thermally conductive filler dispersed therein.

Generally, the conformable component may have the ability to at least partially, and non-destructively, conform to the contour/shape of a surface applying a compressive force thereto. In some embodiments, the conformable component may include any material that can distort, or flow. The conformable component may include a polymeric or oligomeric (or polymeric or oligomeric precursor) fluid or elastomer. The conformable component may include a viscoelastic material. The conformable component may include silicones, acrylics, epoxies, and mixtures thereof. The conformable component may include an adhesive (e.g., pressure sensitive adhesive), a thermally conductive grease, or combinations thereof. Pressure sensitive adhesives useful in the methods of the present disclosure may include, without limitation, natural rubber, styrene butadiene rubber, nitrile rubber, styrene-isoprene-styrene (co)polymers, styrene-butadiene-styrene (co)polymers, styrene-acrylonitrile (co)polymers polyacrylates including (meth)acrylic (co)polymers, epoxy acrylate including acrylic polymer hybrid with liquid/semi-solid epoxy resin, urethane acrylate, polyolefins such as polyisobutylene and polyisoprene, polyurethane, polyvinyl ethyl ether, polysiloxanes, silicones, polyurethanes, polyureas, and blends thereof. In some embodiments, each of the TIM segments 20 may be composed of the same material (or combination of materials). Alternatively, one or more of the TIM segments 20 may be composed of a material (or combination of materials) that is different relative to one or more other TIM segments 20.

In illustrative embodiments, the thermally conductive filler dispersed in the conformable component may include, without limitation, diamond, polycrystalline diamond, silicon carbide, alumina, boron nitride (hexagonal or cubic), boron carbide, silica, graphite, amorphous carbon, aluminum nitride, aluminum, zinc oxide, nickel, tungsten, silver, and combinations thereof. The thermally conductive filler may be in the form of particles, fibers, flakes, other conventional forms, or combinations thereof. The thermally conductive filler may be present in the TIMs in an amount of at least 10 percent by weight. In other embodiments, thermally conductive filler may be present in amounts of at least 20, 30, 40, 50, 60, 70, 80, 90, 95, 96, 97, or 98 weight percent. In other embodiments, thermally conductive filler may be present in the TIMs in an amount of not more than 99, 95, 90, 85, 70 or 50 weight percent. In some embodiments, each of the TIM segments 20 may have the same fillers and the same loading of fillers. Alternatively, one or more of the TIM segments 20 may different fillers, different loading of fillers, or both, relative to one or more other TIM segments 20.

In various embodiments, the substrate upon which the array of TIM segments is disposed may be rigid or flexible. The substrate may have at least a sufficient mechanical integrity to be self-supporting. The substrate may consist essentially of only one layer of material, or it may have a multilayered construction. The substrate may have any shape and thickness.

As will be appreciated by those skilled in the art, the segmented TIMs of the present disclosure may be manufactured in the form of a tape or a sheet-like construction that includes a segmented TIM as an interlayer between an inner and an outer release liner (either or both of which may have a release coating disposed on one or more major surfaces thereof). In this regard, in some embodiments, substrates on or over which the segmented TIMs of the present disclosure may be disposed may include release liners. Examples of suitable release liner substrates include papers, (e.g. polycoated Kraft paper,) and polymeric films (e.g., polyethylene terepthalate, polyolefin, such as polyethylene and polypropylene, and polyethylene naphthalate). Examples of suitable release coatings include, without limitation, silicone, fluorocarbons, polyolefins including, e.g., polyethylene and polypropylene, acrylics, and combinations thereof.

Once the inner release liner is removed, the segmented TIM may be bonded to a heat sink or an electronic component to form an assembly, while the outer release liner may remain in place as a protective cover over the segmented TIM. The outer release liner may subsequently be removed to expose the segmented TIM prior to installation of the assembly in an electronic device. In this regard, in various embodiments, substrates on or over which the segmented TIMs of the present disclosure may be disposed may include heat sinks and/or electronic components.

In some embodiments, the substrate may be a plastic substrate from among polyolefins, e.g. polypropylene (PP), various polyesters, e.g. polyethylene terephthalate (PET), polymethylmethacrylate (PMMA) and other polymers such as polyethylene naphthalate (PEN), polyethersulphone (PES), polycarbonate (PC), polyetherimide (PEI), polyarylate (PAR), polyimide (PI), polyurethane (PU), polysilicones, or combinations thereof. Alternatively, the substrate may be a metal (e.g., Al, Cu, Ni, Ag, Au, Ti, and/or Cr), metal oxide, glass, composite, paper, fabric, non woven, or combinations thereof.

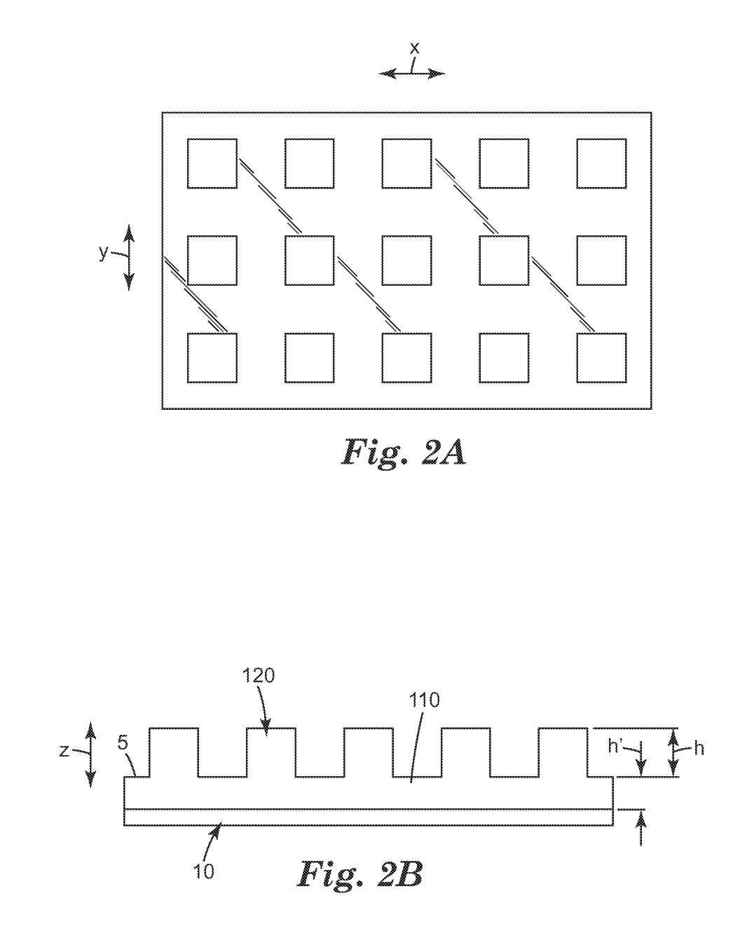

Referring again to FIGS. 1-2, generally, each TIM segment 20 may include a z-dimension, or height h, that generally extends along a z-direction from the major surface 5 of the substrate 10, an x-dimension, or width w, that generally extends along an x-direction oriented substantially orthogonally to the z-dimension that extends along (or substantially parallel to) the major surface 5, and a y-dimension, or length 1, that generally extends along a y-direction oriented substantially orthogonally to the x-dimension that extends along (or substantially parallel to) the major surface 5. While FIGS. 1-2 illustrate a certain number of TIM segments, it is to be appreciated that any number of TIM segments (more or less than that depicted in FIGS. 1-2) may be provided.

Generally, the height, length, and width of the TIM segments 20 may be of any desired magnitude and may be selected to accommodate any particular application. The height, length, and width of the individual TIM segments 20 may be the same throughout the array, or may vary throughout the array. In some embodiments, the average height of the TIM segments 20 may be at least 0.5 μm, at least 1 μm, or even at least 5 μm; the average height of the TIM segments 20 may be no greater than 50 mm, no greater than 25 mm, or even no greater than 10 mm; the average length of the TIM segments 20 may be at least 0.5 μm, at least 1 μm, or even at least 5 μm; the average length of the TIM segments 20 may be no greater than 25 mm, no greater than 10 mm, or even no greater than 1 mm, the average width of the TIM segments 20 may be at least 0.5 μm, at least 1 μm, or even at least 5 μm; and the average width of the TIM segments 20 may be no greater than 25 mm, no greater than 10 mm, or even no greater than 1 mm.

As shown in FIGS. 1-2, the TIM segments 20 may be formed as generally rectangular structures having a top surface 20a and a plurality of side surfaces 20b. It should be noted, however, that the TIM segments 20 need not have the shape shown in FIG. 1. Rather, the TIM segments 20 can have a variety of shapes (including three-dimensional or cross-sectional shapes), including but not limited to, cylindrical, pyramidal, rectangular, triangular, and hook-shaped, parallelepipedal, spherical, hemi-spherical, polygonal, conical, frusto-conical, other suitable shapes, and combinations thereof. It should be further noted that the TIM segments 20 can be in the form of rails or walls that include a z-dimension as well as an x- and/or y-dimension. It should also be noted that the top and side surfaces 20a, 20b may include planar surfaces (as shown in FIGS. 1A-1B), arcuate surfaces, or combinations thereof. For example, in some embodiments, one or more (up to all) of the TIM segments 20 may have an arcuate, domed, or pointed top surface 20a. Top surfaces 20a shaped in this manner may allow for an initial “point contact” with a component surface which compresses the segmented TIMs (e.g., surface of a heat sink or heat source), thereby facilitating the evacuation of air during attachment or joining of components. In illustrative embodiments, each of the TIM segments 20 of the array may have the same shape (or substantially the same shape) or the shapes may vary throughout the array and be formed in any number or combinations of the aforementioned configurations.

Referring still to FIGS. 1-2, in various embodiments, the TIM segments 20 may be laterally spaced with respect to one another in the y-direction by a gap distance G₁, and in the x-direction by a gap distance G₂ to define one or more gaps G extending between adjacent TIM segments. Generally, the gap distances G₁ and G₂ may be selected to provide a variable flow space for the TIMs 20 as they are compressed during attachment or joining of components. The gap distances G₁ and G₂ may be determined, at least in part, based on any or all of (i) the types of materials to be joined or connected by the TIM segments; (ii) the size (e.g., weight) of the components to be attached or joined by the TIM segments; (iii) the composition of the TIM segments (e.g., inherent compressibility of the TIM material); (iv) the size of the TIM (e.g., height, length, width); and (v) the surface profile (e.g., roughness and flatness deviation) of substrates to be joined or connected by the TIM. The gaps distances G₁ and/or G₂ may be the same for each set of adjacent TIM segments 20 or may vary in any desired fashion throughout the array. In this regard, the TIM segments 20 of the present can be disposed in a variety of arrangements, including regular patterns or arrays having constant or variable gaps distances G₁ and G₂ throughout the pattern, or irregular or random arrangements. In illustrative embodiments, the average gap distance G₁ and/or G₂ of the array may be less than 25 mm, less than 10 mm, or even less than 1 mm; and the average gap distance G₁ and G₂ of the array may be at least 5 μm, at least 10 μm, or even at least 100 μm.

In addition to facilitating removal of air at the thermal interface during joining or attachment, the segmented TIMs of the present disclosure may also facilitate compressibility and/or conformability of the TIMs. In various embodiments, the depth, or height of the gaps G₁ and G₂ between the TIM segments 20 (and thus the height of the TIM segments 20), and the width of the gaps G₁ and G₂ may be selected to allow for a desired amount of compressibility and/or conformability of the segmented TIMs 20. In this regard, the average aspect ratio of width to thickness and/or length to thickness of the TIMs 20 may be selected to range from 1:10 and 20:1, 1:10 and 10:1, 1:5 and 10:1, or even 1:2 and 5:1, depending on the desired amount of compressibility and/or conformability of the segmented TIMs 20. Further in this regard, the average volume ratio of the gaps of an array to the TIM segments of the array may be selected to range from 1:10 and 10:1, 1:5 and 5:1, or even 1:3 and 3:1, depending on the desired amount of compressibility and/or conformability of the segmented TIMs 20.

Referring now to FIGS. 2A-2B, illustrated are schematic top and side views, respectively, of a segmented TIM in accordance with another embodiment of the present disclosure. The segmented TIM of FIGS. 2A-2B shares many of the same elements and features described above with reference to the illustrated embodiments of FIGS. 1A-1B. Reference is made to the description above accompanying FIGS. 1A-1B for a more complete description of the features and elements (and alternatives to such features) of the embodiment illustrated in FIGS. 2A-2B.

As shown in FIGS. 2A-2B, in various embodiments, the present disclosure relates to a segmented TIM provided in the form of a base layer 110 and two or more TIM segments 120 generally extending along a z-direction from the base layer 110. As with previous embodiments, the TIM segments 120 may have a height h. The base layer 110 may include a z-dimension, or height h′, that generally extends along the z-direction. The height h′ of the base layer 110 may be at least 0.5 μm, at least 1 μm, or even at least 5 μm; the height h′ of the base layer 110 may be no greater than 5 mm, no greater than 2.5 mm, or even no greater than 1 mm. While the base layer 110 is depicted as having approximately a constant height h′, it should be understood that this parameter can change throughout the TIM and need not be a constant or fixed distance over the entire TIM. Further, while FIGS. 2A-2B depict the TIM segments 120 and base layer 110 disposed on a major surface 5 of a substrate 10, it is to be understood that the TIM segments 120 and base layer 110 may be provided separately from a substrate 10.

Referring still to the embodiment of FIGS. 2A-2B, in some embodiments, the base layer 110 may be formed of a material (or combination of materials) that is the same as that of one or more (up to all) of the segments 120, or the base layer 110 may be formed of a material that is different (e.g., in terms of conformable component material, conductive filler, and/or loading of conductive filler) than the material of one or more (up to all) of the TIM segments 120. The base layer 110 may be integrally formed with the segments 120 or may be coupled thereto via a suitable connection mechanism (e.g., adhesive). While FIGS. 2A-2B depict TIM segments 120 on only one side of the base layer 110, it is to be appreciated TIM segments 120 may be provided on both sides of the base layer 110. Additionally, it is to be appreciated that the above discussion regarding the configuration of the TIM segments 20 (e.g., size, shape, gap distances, etc.) applies with equal force to the TIM segments 120.

In some embodiments, in conjunction with any of the previously described embodiments, one or more (up to all) of the gaps G provided between and among the array of TIM segments 20, 120 may be at least partially filled with a fluid. Generally, any fluid having a lower viscosity than the material that forms the TIM segments 20, 120 may be employed as the gap filling fluid. Suitable gap filling fluids may include air, liquid adhesive, organic liquid grease, non-electrically conductive fluorochemical solutions, or combinations thereof. In various embodiments, the gap filling fluid comprises a fluid other than air. The gap filling fluid may fill any portion (up to all) of the volume of a gap G. Each of the gaps G may be provided with the same gap filling fluid and/or filling levels, or may be provided with different filling fluids and/or filling levels. Generally, the gap filling fluid may be provided to improve the heat transfer efficiency of the segmented TIM by increasing the thermal conductivity of any portion of the gaps G (i.e., voids) that remain in the TIM after compression between components to be joined or connected by the TIM.

Generally, the heat transfer efficiency of a TIM in a given application may be determined based on the thermal conductivity (k) of the TIM, the ability of the TIM to spread-out over and contact the substrate surfaces (“wet-out”), and the thickness of the TIM in the direction of heat transfer (heat transfer is inversely proportional to the thickness).

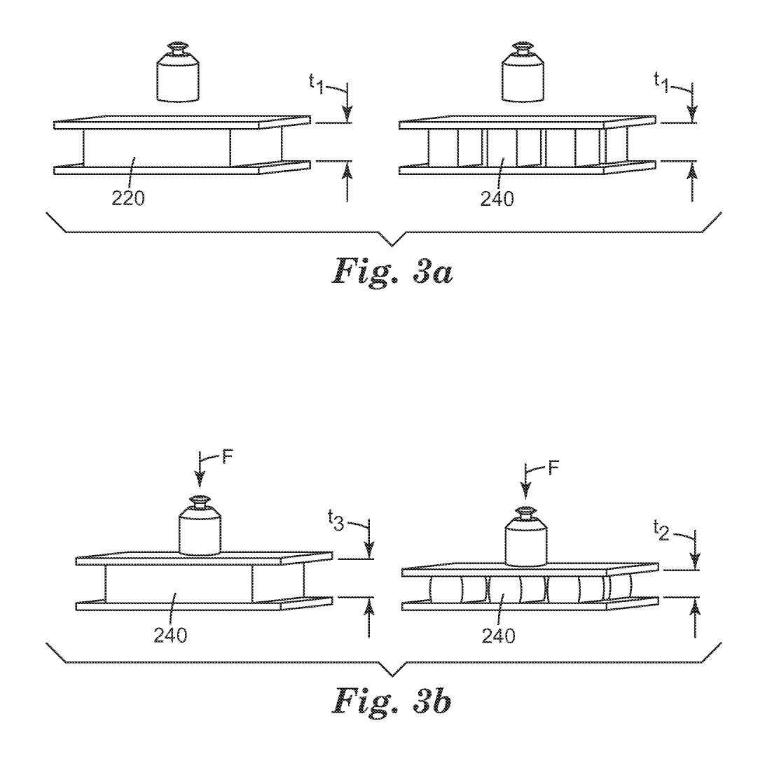

In some embodiments, the segmented TIMs of the present disclosure may provide a substantially improved combination of conformability and thermal conductivity. For example, as will be appreciated by those skilled in the art, the segmented design described herein may impart an effective lower spring constant (k′) to the TIM (relative to the same material in a uniform or substantially uniform sheet). Consequently, for the same pressure applied to a given TIM, the segmented TIMs of the present disclosure will exhibit increased compression, resulting in a reduced TIM thickness at the heat transfer interface and, in turn, improved heat transfer efficiency. This concept may be observed with reference to FIGS. 3a and 3b, which illustrate perspective side views of a uniform sheet of a TIM 220 and a segmented TIM 240 of identical material, before and after compression, respectively, between components 250, 260 via a compressive force F. As shown in FIG. 3a, initially, the TIM 220 and the segmented TIM 240 have the same thickness t₁. However, as shown in FIG. 3b, upon application of an identical compressive force F, due to the effective lower spring constant, the thickness t₂ of the segmented TIM 240 is less than the thickness t₃ of the TIM 220. As a result of this reduced thickness, the theoretical heat transfer efficiency of the segmented TIM 240 is superior to that of the uniform sheet of a TIM 220.

In addition to providing a lower effective spring constant (k′), the segmented TIMs of the present disclosure may also accommodate increased conformability of the TIM to uneven surfaces. Specifically, the open areas, or gaps, provided by the segmented design may provide a variable flow space for any TIM segments of the array that are subjected to compressive forces greater than that of other of the TIM segments. As previously discussed, such variation in compression experienced by TIMs is commonplace due to, for example, uneven surfaces on the heat source and/or heat sink surfaces to be joined or connected by the TIM. Those skilled in the art will appreciate that this variable flow space allows for greater compressibility/conformability of the TIM and, in turn, increased surface contact between the TIM and the component surface(s), thereby improving the heat transfer efficiency. As an example of this, assume a segmented TIM of the present disclosure is to be compressed between component surfaces (e.g., surfaces of a heat generating electronic component and thermal dissipation member) having generally concave surface profiles. In this scenario, due to the uneven/concave surface profiles, upon compression between the components, the outer or peripheral TIM segments of the array will be subjected to greater compressive forces than that of the middle segments. As a result of the variable flow space provided by the segmented design, greater compressibility of these outer TIM segments is provided. Consequently, the inner TIM segments are more likely to engage with the middle recessed areas of the concave surfaces, resulting in an overall increased surface engagement of the

TIM with the uneven component surfaces. In this fashion, the heat transfer efficiency of the segmented TIMs of the present disclosure is further enhanced.

The present disclosure further relates to methods of making the above-described segmented TIMs. In some embodiments, the segmented TIMs may be manufactured by casting a TIM which, as described above, may include a conformable component and thermally conductive particles, into a mold. The mold may be configured to provide the TIM with a desired segment pattern (e.g., number of TIM segments; height, length, and width of TIM segments; gap distances). Next, a substrate (e.g., release liner) may optionally be applied to the mold. The TIM may then be removed from the mold to produce a segmented TIM, optionally disposed on or over a substrate. Subsequently, optionally, one or more of the gaps provided between and among the TIM segments may be at least partially filled with a fluid utilizing any conventional fluid deposition technique. Optionally, a second substrate (e.g., release liner) may then be applied to the segmented TIM opposite the first substrate. Finally, the segmented TIMs and optional substrates may be converted into any desired form including sheets, rolls, pads, or the like.

In various embodiments, the above-described mold may serve as both the substrate and the molding surface. For example, a polymeric film may be molded (e.g., compression molded) to form a desired pattern on at least one surface, and then the TIM may be filled into that surface. The mold may be reused as part of manufacturing, or may be removed by an end user. Suitable methods for producing the mold/substrate may include cast and cure, thermoforming, extrusion casting, embossing, and the like. Suitable materials for the mold/substrate include, for example, thermoset or thermoplastic polymers, including acrylates, polyolefins, including polyethylene, polypropylene, polylactic acid, and PHAs. In further embodiments, the segmented TIMs may be applied on a substrate or liner in any conventional manner, for example, by a direct process such as spraying, dipping, casting, or extrusion, knife, roller, gravure, wire rod, or drum coating. Portions of the TIM may then be removed by, for example, machining, scraping, etching, coronal discharge, or other means to form a segmented TIM. In still further embodiments, the segmented TIMs may be formed utilizing any suitable printing technique (e.g., screen printing).

The present disclosure is further directed to a method of making an electronic device. In embodiments in a segmented TIM is disposed between first and second release liners, the first release liner may be at least partially stripped to expose at least a region of the segmented TIM. In certain embodiments, the first release liner may release cleanly from the TIM with little or no material remaining on the release surface of the first release liner. Next, the exposed surface of the segmented TIM may be applied on a first substrate such as, for example, an electronic component or a thermal dissipative member, to form an electronic assembly. At this point, a mild pressure may be applied to the TIM to ensure that it has wet the substrate and, to the extent possible, any air trapped air between the TIM and the first substrate is removed. In the electronic assembly, the second release liner may remain intact over the segmented TIM to protect the TIM and prevent contamination until the assembly is ready for attachment to a second substrate (e.g., another electronic component). The assembly may then be prepared for attachment to the second substrate by stripping away at least a portion of the second release liner and exposing at least a region of the TIM. As with the first release liner, the release surface of the second release liner may release cleanly from the TIM with little or no material remaining on the second release liner. The TIM may then be positioned at the interface between the first and second substrates to form an electronic device.

Specific applications for the segmented TIMs of the present disclosure include, but are not limited to, attachment of a microelectronic die or chip to at least one thermal dissipation member in an electronic device. Exemplary electronic devices include a power module, an IGBT, a DC-DC converter module, a solid state relay, a diode, a light-emitting diode (LED), a power MOSFET, an RF component, a thermoelectric module, a microprocessor, a multichip module, an ASIC or other digital component, a power amplifier, or a power supply.

1. A thermal interface material comprising:
a conformable component; and
a thermally conductive filler dispersed in the conformable component;
wherein the material is provided in at least two segments laterally spaced from one another to define one or more gaps, each of the segments having a length, a width, and a height; and
wherein the average aspect ratio of length to height and/or width to height of the at least two segments is between 1:10 and 10:1.

2. The thermal interface material of claim 1, wherein the average aspect ratio of length to height and/or width to height of the at least two segments is between 1:2 and 5:1.

3. The thermal interface material of claim 1, wherein the average height of the at least two segments is at least 0.5 μm.

4. The thermal interface material claim 1, wherein the conformable component comprises a polymeric or oligomeric fluid or elastomer.

5. The thermal interface material of claim 1, wherein the conformable component comprises a pressure sensitive adhesive.

6. The thermal interface material of claim 1, wherein the conductive filler comprises diamond, polycrystalline diamond, silicon carbide, alumina, boron nitride (hexagonal or cubic), boron carbide, silica, graphite, amorphous carbon, aluminum nitride, aluminum, zinc oxide, nickel, tungsten, silver, or combinations thereof.

7. The thermal interface material of claim 1, wherein the conductive filler is present in an amount of at least 50 percent by weight based on the total weight of the composition.

8. The thermal interface material of claim 1, wherein the material comprises a base layer, and wherein the at least two segments generally extend in a first direction from the base layer.

9. The thermal interface material of 8, wherein a height of the base layer in the first direction is between 1 μm and 1 mm.

10. The thermal interface material of claim 1, wherein a fluid other than air at least partially fills one or more of the gaps.

11. An article comprising:
a substrate having a major surface;
wherein the thermal interface material of claim 1 is disposed on or over the major surface.

12. The article of claim 11, wherein the substrate comprises a release liner.

13. The article of claim 11, wherein the substrate comprises a heat generating electronic component or a thermal dissipation member.

14. An article comprising:
a first release liner comprising a first release surface; and
a second release liner comprising a second release surface;
wherein the thermal interface material of claim 1 is disposed between the first and second release surfaces.

15. A method for making a thermal interface material, the method comprising:
providing a thermal interface material, the thermal interface material comprising a conformable component and thermally conductive particles;
casting the thermal interface material into a mold, wherein the mold is configured to provide the thermal interface material with a pattern whereby the thermal interface material is provided in at least two segments laterally spaced from one another to define one or more gaps, each of the segments having a length, a width, and a height, and wherein the average aspect ratio of length to height and/or width to height of the at least two segments is between 1:10 and 10:1;
removing the thermal interface material from the mold.

16. The method of claim 15, further comprising the step of applying a substrate to the mold.

17. A method for making an electronic device, the method comprising:
providing an article comprising:
a first release liner comprising a first release surface, and
a second release liner comprising a second release surface,
wherein the thermal interface material of claim 1 is disposed between the first and second release surfaces;
removing the first release liner to at least partially expose thermal interface material; and
applying the thermal interface material to a substrate comprising an electronic or a thermal dissipative member.
